(19) United States
(12) Patent Application Publication
(10) Pub. No.: US 2026/0271688 A1
(43) Pub. Date: Sep. 10, 2026

(54) SYSTEMS AND METHODS FOR CONTROLLING POROUS RESISTIVITIES

(71) Applicant: IQE plc, St. Mellons, Cardiff (GB)

(72) Inventors: Richard HAMMOND, St. Mellons, Cardiff (GB); Andrew CLARK, St. Mellons, Cardiff (GB)

(21) Appl. No.: 19/135,995

(22) PCT Filed: Dec. 6, 2023
(86) PCT No.: PCT/EP2023/084576

§ 371 Date: Jun. 5, 2025

(30) Foreign Application Priority Data
Dec. 12, 2022 (GB) 2218651.4

(51) Int. Cl. H10W 10/10; H10D 30/60; H10D 86/00; H10P 14/60; H10P 14/69; H10P 50/61; H10P 90/00; H10W 10/00

(52) U.S. Cl. CPC H10W 10/181; H10P 14/665; H10P 14/6903; H10P 50/613; H10P 90/1912; H10W 10/018; H10D 30/60; H10D 86/201

(57) ABSTRACT

A method for forming a layered structure can include forming a porous layer by electrochemical etching a portion of a substrate. The substrate can have a first resistivity no greater than about 10 Ω·cm. The porous layer can have a second resistivity greater than the first resistivity. The second resistivity can be dependent upon the first resistivity.

### BACKGROUND

### Field

The present disclosure relates to porous apparatuses, systems, and methods, for example, porous apparatuses, systems, and methods for controlling the resistivity of a porous layer based on the starting resistivity of a substrate wafer to improve harmonic performance of a semiconductor.

### Background

Semiconductor-on-insulator (SOI) structures are commonly employed to realize radio frequency (RF) designs where low signal leakage is required. These SOI structures use a buried oxide (BOX) under a top device layer in which RF circuit components, such as transistors and/or passive components, can be fabricated. A handle wafer functioning as a substrate under the BOX can result in signal leakage due to RF fringing fields penetrating into the substrate.

Current incumbent RF-SOI technology utilizes a trap-rich SOI to reduce carrier accumulation due to RF fringing fields and improve harmonic losses. A trap-rich layer (e.g., polysilicon) is formed between the handle wafer and the BOX to minimize parasitic surface conduction effects that can adversely affect RF devices in the top device layer. In addition, to further improve substrate harmonic losses, high-resistivity handle wafers (e.g., greater than 3,000 Ω·cm) are used to reduce the amount of free charge carriers. However, this approach requires costly and/or specialized fabrication techniques.

Porous semiconductors are an alternative to SOI substrates and fully insulating substrates such as glass. Porous semiconductors can achieve high-resistivity properties on a standard CMOS silicon wafer, rather than a high-resistivity SOI wafer. Porosification can form a porous region with a particular thickness and porosity in a layer or substrate. For example, electrochemically etching a standard low-resistivity (e.g., 1 Ω·cm) silicon wafer can form a thick (e.g., greater than 10 microns) porous silicon surface layer. The porous etch can deplete free charge carriers within the silicon and increase a resistivity of the porous silicon layer by several orders of magnitude (e.g., from 1 Ω·cm to greater than 5,000 Ω·cm). The high-resistivity and low relative permittivity (e.g., about 2.2) of porous silicon can suppress harmonic losses by several orders of magnitude more than trap-rich SOI.

Further, porous silicon provides an epitaxy platform to regrow a defect-free, single crystal silicon epilayer. Epitaxy refers to crystal growth or material deposition in which new crystalline layers are formed with one or more well-defined orientations. Epitaxy can be used to grow high quality, single crystal semiconductors atop the porous layer. For example, such an epilayer can be used as a device layer for RF circuit components (e.g., an RF CMOS switch).

However, the relationship between a resistivity of the starting substrate and a resistivity of the resulting porous layer formed after porosification is not well-understood. Further, better control and optimization of the resulting porous layer resistivity may be needed depending on the specific device application (e.g., RF CMOS switch). In addition, fine-tuning resistivities of high-resistivity porous layers are needed to adequately suppress harmonic losses and crosstalk in layered structures for large volume communication devices (e.g., 5G mmWave with signals above 20 GHz).

### SUMMARY

Accordingly, there is a need for a method of controlling and/or optimizing the resistivity of the porous layer by varying and selecting the resistivity of the substrate material in order to improve the harmonic performance of the semiconductor.

In some aspects, a method for forming a layered structure can include forming a porous layer by electrochemical etching a portion of a substrate. In some aspects, the substrate can have a first resistivity no greater than about 10 Ω·cm. In some aspects, the porous layer can have a second resistivity greater than the first resistivity. In some aspects, the second resistivity can be dependent upon the first resistivity. Advantageously the disclosed method can allow the second resistivity to be controlled or optimized by varying the first resistivity.

In some aspects, the second resistivity is exponentially dependent upon the first resistivity. In some aspects, the second resistivity (Ω₂) is dependent upon the first resistivity (Ω₁) such that Ω₂=Ae^{BΩ}^{₁}. In some aspects, A is in a range between about 13 and 19.3 and B is in a range between about 7 and 9.7. In some aspects, a ratio of the second resistivity to the first resistivity is between about 250 and about 1,000. Advantageously the disclosed relationship between the first resistivity and the second resistivity can allow the second resistivity to be selected or optimized by varying the first resistivity.

In some aspects, the first resistivity is between about 0.01 Ω·cm and 10 Ω·cm, and the second resistivity is between about 10 Ω·cm and 50,000 Ω·cm. In some aspects, the first resistivity is between about 0.05 Ω·cm and about 0.10 Ω·cm, and the second resistivity is between about 15 Ω·cm and about 25 Ω·cm. In some aspects, the first resistivity is between about 0.20 Ω·cm and about 0.30 Ω·cm, and the second resistivity is between about 150 Ω·cm and about 250 Ω·cm. In some aspects, the first resistivity is between about 0.8 Ω·cm and about 1 Ω·cm, and the second resistivity is at least about 10,000 Ω·cm. In some aspects, the first resistivity is between about 1 Ω·cm and about 5 Ω·cm, and the second resistivity is at least about 24,000 Ω·cm. In some aspects, the second resistivity is at least 5,000 Ω·cm. In some aspects, the second resistivity is at least 50,000 Ω·cm. In some aspects, the second resistivity is at least 100,000 Ω·cm. In some aspects, the second resistivity is at least 500,000 Ω·cm. In some aspects, the second resistivity is at least 760,000 Ω·cm. Advantageously a value of the second resistivity disclosed above can be obtained by selecting the first resistivity within the values disclosed above.

In some aspects, the method can further include forming an epitaxial layer on the porous layer. In some aspects, the method can further include forming a semiconductor device in the epitaxial layer. In some aspects, the method can further include forming a semiconductor device, for example a passive device such as an inductor or filter, in the porous layer. Advantageously the semiconductor device formed in the epitaxial layer or the porous layer can have improved RF performance due to suppression of harmonic losses at radio frequencies in the porous layer.

In some aspects, a layered structure can include a porous layer formed over a substrate. In some aspects, the substrate can have a first resistivity no greater than about 10 Ω·cm. In some aspects, the porous layer can have a second resistivity greater than the first resistivity. In some aspects, the second resistivity can be dependent upon the first resistivity. Advantageously the disclosed layered structure can allow the second resistivity to be controlled or optimized by varying the first resistivity.

In some aspects, the second resistivity is exponentially dependent upon the first resistivity. In some aspects, the second resistivity (Ω₂) is dependent upon the first resistivity (Ω₁) such that Ω₂=Ae^{BΩ}^{₁}, where A is in a range between about 13 and 19.3 and B is in a range between about 7 and 9.7. In some aspects, a ratio of the second resistivity to the first resistivity is between about 250 and about 1,000. In some aspects, a ratio of the second resistivity to the first resistivity is at least 24,000. Advantageously the disclosed relationship between the first resistivity and the second resistivity can allow the second resistivity to be selected or optimized by varying the first resistivity.

In some aspects, the first resistivity is between about 0.01 Ω·cm and 10 ∩·cm, and the second resistivity is between about 10 Ω·cm and 50,000 Ω·cm. In some aspects, the first resistivity is between about 0.01 Ω·cm and 10 Ω·cm, and the second resistivity is between about 10 Ω·cm and 100,000 Ω·cm. In some aspects, the first resistivity is between about 0.01 Ω·cm and 50 ∩·cm, and the second resistivity is between about 50 Ω·cm and 500,000 Ω·cm. In some aspects, the first resistivity is between about 0.01 Ω·cm and 50 Ω·cm, and the second resistivity is between about 50 Ω·cm and 760,000 Ω·cm. In some aspects, the first resistivity is between about 0.05 Ω·cm and about 0.10 Ω·cm, and the second resistivity is between about 15 Ω·cm and about 25 Ω·cm. In some aspects, the first resistivity is between about 0.20 Ω·cm and about 0.30 Ω·cm, and the second resistivity is between about 150 Ω·cm and about 250 Ω·cm. In some aspects, the first resistivity is between about 0.8 Ω·cm and about 1 Ω·cm, and the second resistivity is at least about 10,000 Ω·cm. In some aspects, the first resistivity is between about 1 Ω·cm and about 5 Ω·cm, and the second resistivity is at least about 24,000 Ω·cm. Advantageously a value of the second resistivity disclosed above can be obtained by selecting the first resistivity within the values disclosed above.

In some aspects, the layered structure can further include an epitaxial layer formed on the porous layer. In some aspects, the layered structure can further include a semiconductor device formed in the epitaxial layer. In some aspects, the method can further include forming a semiconductor device, for example a passive device such as an inductor or filter, in the porous layer. Advantageously the semiconductor device in the epitaxial layer or the porous layer can have improved RF performance due to suppression of harmonic losses at radio frequencies in the porous layer.

Implementations of any of the techniques described above can include a system, a method, a process, a device, and/or an apparatus. The details of one or more implementations are set forth in the accompanying drawings and the description below. Other features will be apparent from the description and drawings, and from the claims.

Further features and exemplary aspects of the aspects, as well as the structure and operation of various aspects, are described in detail below with reference to the accompanying drawings. It is noted that the aspects are not limited to the specific aspects described herein. Such aspects are presented herein for illustrative purposes only. Additional aspects will be apparent to persons skilled in the relevant art(s) based on the teachings contained herein.

### BRIEF DESCRIPTION OF THE DRAWINGS/FIGURES

The accompanying drawings, which are incorporated herein and form part of the specification, illustrate the aspects and, together with the description, further serve to explain the principles of the aspects and to enable a person skilled in the relevant art(s) to make and use the aspects.

FIG. 1 is a schematic cross-sectional illustration of a previously known trap-rich SOI layered structure.

FIG. 2 is a schematic cross-sectional illustration of a porosification system, according to an exemplary aspect.

FIG. 3A is a schematic cross-sectional illustration of a porous layered structure, according to an exemplary aspect.

FIG. 3B is a schematic cross-sectional illustration of a porous layered structure, according to an exemplary aspect.

FIG. 4 is a schematic circuit diagram of a transceiver including an RF switch employing stacked transistors, according to an exemplary aspect.

FIG. 5A is a schematic cross-sectional illustration of a porous layered structure, according to an exemplary aspect.

FIG. 5B is a schematic cross-sectional illustration of a porous layered structure, according to an exemplary aspect.

FIG. 6 is an illustrative graph showing a correlation between substrate resistivity and porous layer resistivity, according to an exemplary aspect.

FIG. 7 is an illustration of method steps to manufacture a porous layered structure, according to an exemplary aspect.

The features and exemplary aspects of the aspects will become more apparent from the detailed description set forth below when taken in conjunction with the drawings, in which like reference characters identify corresponding elements throughout. In the drawings, like reference numbers generally indicate identical, functionally similar, and/or structurally similar elements. Additionally, generally, the left-most digit(s) of a reference number identifies the drawing in which the reference number first appears. Unless otherwise indicated, the drawings provided throughout the disclosure should not be interpreted as to-scale drawings.

### DETAILED DESCRIPTION

This specification discloses one or more aspects that incorporate the features of this present invention. The disclosed aspect(s) merely exemplify the present invention. The scope of the invention is not limited to the disclosed aspect(s). The present invention is defined by the claims appended hereto.

The aspect(s) described, and references in the specification to “one aspect,” “an aspect,” “an example aspect,” “an exemplary aspect,” etc., indicate that the aspect(s) described can include a particular feature, structure, or characteristic, but every aspect may not necessarily include the particular feature, structure, or characteristic. Moreover, such phrases are not necessarily referring to the same aspect. Further, when a particular feature, structure, or characteristic is described in connection with an aspect, it is understood that it is within the knowledge of one skilled in the art to affect such feature, structure, or characteristic in connection with other aspects whether or not explicitly described.

Spatially relative terms, such as “beneath,” “below,” “lower,” “above,” “on,” “upper” and the like, can be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus can be otherwise oriented (rotated 90 degrees or at other orientations) and the spatially relative descriptors used herein can likewise be interpreted accordingly.

The term “about” or “substantially” or “approximately” as used herein means the value of a given quantity that can vary based on a particular technology. Based on the particular technology, the term “about” or “substantially” or “approximately” can indicate a value of a given quantity that varies within, for example, 0.1-10% of the value (e.g., ±0.1%, ±1%, ±2%, ±5%, or ±10% of the value).

The term “epitaxy” or “epitaxial” as used herein means crystalline growth of material, for example, via high temperature deposition. Epitaxy can be effected in a molecular beam epitaxy (MBE) tool in which layers are grown on a heated substrate in an ultra-high vacuum environment. Elemental sources are heated in furnaces and directed towards the substrate without carrier gases. The elemental constituents react at the substrate surface to create a deposited layer.

Epitaxy can also be performed in a vapor phase epitaxy (VPE) tool, also known as a chemical vapor deposition (CVD) tool. CVD is the formation of stable solids by decomposition of gaseous chemicals using heat, plasma, ultraviolet, or other energy sources. Silicon epitaxy can be produced by CVD using heat as the energy source to decompose gaseous chemicals. For example, silicon and dopant atoms can be brought to a single crystal surface by gaseous transport to form a doped epitaxial layer. The CVD tool can be controlled by reactor design variables and operator variables, each of which can influence the uniformity, productivity, and quality of the epitaxial layer.

Epitaxy can also be performed in a metal-organic vapor phase epitaxy (MOVPE) tool, also known as a metal-organic chemical vapor deposition (MOCVD) tool. Compound metal-organic and hydride sources flow over a heated surface using a carrier gas, for example, hydrogen. Epitaxial deposition in the MOCVD tool occurs at higher pressures than in an MBE tool. The compound constituents are cracked in the gas phase and then reacted at the surface to grow layers of desired composition.

The term “compound semiconductor material” or “Group III-V semiconductor” or “III-V semiconductor” or “III-V material” as used herein means including one or more materials from Group III of the periodic table (e.g., group 13 elements: boron (B), aluminum (Al), gallium (Ga), indium (In), thallium (Tl)) with one or more materials from Group V of the periodic table (e.g., group 15 elements: nitrogen (N), phosphorus (P), arsenic (As), antimony (Sb), bismuth (Bi)). The compounds have a 1:1 combination of Group III and Group V regardless of the number of elements from each group. Subscripts in chemical symbols of compounds refer to the proportion of that element within that group. For example, Al_{0.25}Ga_{0.75}As means the Group III part comprises 25% Al, and thus 75% Ga, while the Group V part comprises 100% As.

The term “Group IV semiconductor” as used herein indicates comprising one or more materials from Group IV of the periodic table (e.g., group 14 elements: carbon (C), silicon (Si), germanium (Ge), tin (Sn), lead (Pb)). An alloy can be formed from one or more Group IV elements. Subscripts in chemical symbols of the alloy refer to the proportion of that element within the alloy. For example, Si_{0.8}Ge_{0.2} means the alloy comprises 80% Si and 20% Ge.

The term “Group II-VI semiconductor” as used herein indicates comprising one or more materials from Group II of the periodic table (e.g., group 12 elements: zinc (Zn), cadmium (Cd), mercury (Hg)) with one or more materials from Group VI of the periodic table (e.g., group 16 elements: oxygen (O), sulfur (S), selenium (Se), tellurium (Te)).

The term “substrate” as used herein means a planar wafer on which subsequent layers may be deposited, formed, or grown. A substrate may be formed of a single element (e.g., Si) or a compound material (e.g., GaAs), and may be doped or undoped. In some aspects, for example, a substrate can include Si, Ge, GaAs, GaN, GaP, GaSb, InP, InSb, a Group IV semiconductor, a Group III-V semiconductor, a Group II-VI semiconductor, graphene, or silicon carbide (SiC).

A substrate may be on-axis, that is where the growth surface aligns with a crystal plane. For example, a substrate can have <100> crystal orientation. Reference herein to a substrate in a given crystal orientation also encompass a substrate which is miscut by up to about 20° towards another crystallographic direction. For example, a (100) substrate miscut towards the (111) plane.

The term “monolithic” as used herein means a layer or substrate comprising bulk (e.g., single) material throughout. Alternatively, the layer or substrate may be porous for some or all of its thickness.

The term “doping” or “doped” as used herein means that a layer or material contains a small impurity concentration of another element (dopant) which donates (donor) or extracts (acceptor) charge carriers from the parent material and therefore alters the conductivity. Charge carriers may be electrons or holes. A doped material with extra electrons is called n-type while a doped material with extra holes (fewer electrons) is called p-type.

The term “crystalline” as used herein means a material or layer with a single crystal orientation. In epitaxial growth or deposition, subsequent layers with the same or similar lattice constant follow the registry of the previous crystalline layer and therefore grow with the same crystal orientation or crystallinity. As will be understood by a person of ordinary skill in the art, crystal orientation, for example, <100> means the face of cubic crystal structure and encompasses [100], [010], and [001] orientations using the Miller indices. Similarly, for example, <0001> encompasses [0001] and [000-1], except if the material polarity is critical. Also, integer multiples of any one or more of the indices are equivalent to the unitary version of the index. For example, (222) is equivalent to (111).

The term “lattice matched” as used herein means that two crystalline layers have the same, or similar, lattice spacing such that the second layer will tend to grow isomorphically (e.g., same crystalline form) on the first layer, also known as pseudomorphic (e.g., near-lattice-matched).

The term “lattice constant” as used herein means the smallest periodicity of a crystalline lattice along a certain crystal orientation. For example, the unstrained lattice spacing of a crystalline unit cell.

The term “deposition” as used herein means the depositing of a layer on another layer or substrate. Deposition encompasses epitaxy, physical vapor deposition (PVD), electron-beam PVD (EBPVD), sputter deposition, chemical vapor deposition (CVD), plasma-enhanced CVD (PECVD), atomic layer deposition (ALD), powder bed deposition, and/or other known techniques to deposit material in a layer.

The term “lateral” or “in-plane” as used herein means parallel to the surface of the substrate and perpendicular to the growth direction.

The term “vertical” or “out-of-plane” as used herein means perpendicular to the surface of the substrate and in the growth direction.

The term “porosifying” or “porosification” as used herein means forming a porous region with a particular thickness and porosity in a layer or substrate. The porosity of a material is affected by electrolyte concentration, electrolyte current density, electrolyte current fluid velocity, anodization time, temperature, and/or material doping. Porosifying can include electrochemical (EC) etching or photoelectrochemical (PEC) etching to form one or more porous layers in a layer or substrate. For example, an electrolyte current (e.g., hydrofluoric acid (HF) at 100 mA/cm² and 20° C.) can be applied to a layer to form one or more porous layers.

The term “porous region” or “porous layer” as used herein means a layer that includes air or vacuum pores, with the porosity defined as the proportion of the area which is occupied by the pores rather than the bulk (e.g., single) material (e.g., a percentage %). The porosity can vary through the thickness of the layer. For example, the layer may be porous in one or more sublayers. The layer may include an upper portion which is porous and a lower portion that is non-porous. The porosity may be constant or variable within the porous region. Where the porosity is variable, the porosity may be linearly varied through the thickness, or may be varied according to a different function, for example, quadratic, logarithmic, or a step function. Pores in the porous layer can be microporous (e.g., less than 2 nm pore size), mesoporous (e.g., 2 nm to 50 nm pore size), nanoporous (e.g., less than 100 nm pore size), or macroporous (e.g., 50 nm to 1000 nm pore size).

Numerical values, including endpoints of ranges, can be expressed herein as approximations preceded by the term “about,” “substantially,” “approximately,” or the like. In such cases, other aspects include the particular numerical values. Regardless of whether a numerical value is expressed as an approximation, two aspects are included in this disclosure: one expressed as an approximation, and another not expressed as an approximation. It will be further understood that an endpoint of each range is significant both in relation to another endpoint, and independently of another endpoint.

Before describing aspects of the present disclosure in more detail, it is instructive to present exemplary layered structures, porosification systems, and environments in which aspects of the present disclosure may be implemented.

### Exemplary Layered Structures and Porosification Systems

As discussed above, porous semiconductors are an alternative to current incumbent RF-SOI technology that utilize trap-rich SOI substrates. Porosification can form a thick porous region with a particular thickness (e.g., greater than 2 microns) and porosity (e.g., about 35% to 65%) in a layer or substrate, and achieve high-resistivity (e.g., greater than 5,000 Ω·cm) on a standard CMOS wafer (e.g., silicon wafer). The high-resistivity porous layer (e.g., porous silicon) can suppress harmonic losses by several orders of magnitude more than trap-rich SOI. Further, the porous layer provides an epitaxy platform to regrow a defect-free, single crystal epilayer. For example, such an epilayer can be used as a device layer for RF circuit components (e.g., an RF CMOS switch).

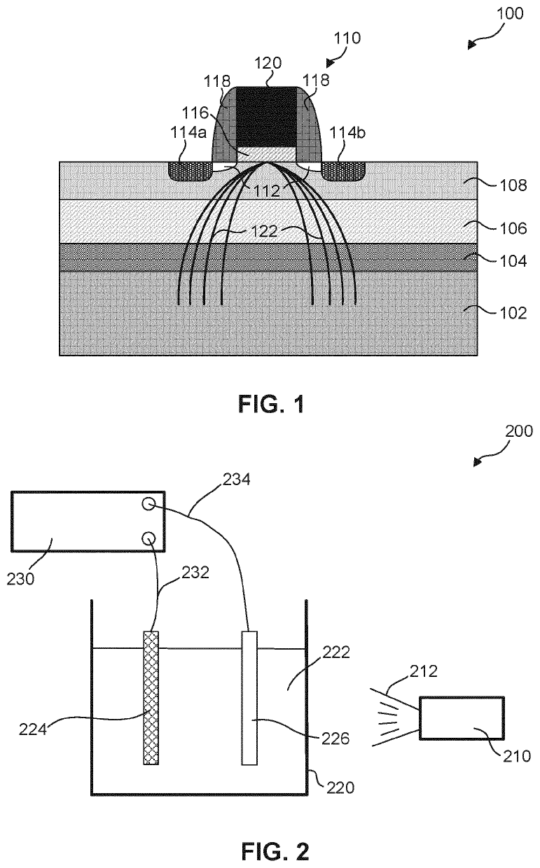

FIG. 1 illustrates trap-rich SOI layered structure 100, according to a previously known configuration. In the example shown in FIG. 1, trap-rich SOI layered structure 100 includes substrate 102 (e.g., silicon), trap-rich layer 104 (e.g., polysilicon), buried oxide (BOX) layer 106 (e.g., silicon dioxide), semiconductor layer 108 (e.g., silicon), and semiconductor device 110 (e.g., MOSFET) in semiconductor layer 108. According to such a configuration, semiconductor device 110 produces RF field lines 122 that penetrate (bleed) through trap-rich layer 104 and BOX layer 106 into substrate 102. This configuration causes significant harmonic losses, crosstalk, and parasitic surface conduction effects.

Semiconductor device 110 can include lightly doped regions 112, source/drain junctions 114a, 114b, gate oxide 116, spacers 118, and gate 120. Lightly doped regions 112 can be implanted with a dopant of a different type (e.g., n-type) than the corresponding semiconductor layer 108 (e.g., p-type). Source/drain junctions 114a, 114b can be implanted with a dopant of the same type as adjacent lightly doped regions 112, but having a higher concentration than lightly doped regions 112. Gate oxide 116 can comprise an electrical insulator, for example, silicon dioxide (SiO₂). Spacers 118 can comprise an electrical insulator, for example, silicon nitride (SiN). Gate 120 can comprise an electrical conductor, for example, polysilicon.

FIG. 2 illustrates porosification system 200, according to an exemplary aspect. Porosification system 200 can be configured to form one or more porous layers in a layer or substrate. In some aspects, porosification system 200 can utilize electrochemical (EC) etching, photoelectrochemical (PEC) etching, or a combination thereof to form one or more porous layers. Although porosification system 200 is shown in FIG. 2 as a stand-alone apparatus and/or system, aspects of this disclosure can be used with other apparatuses, systems, and/or methods.

As shown in FIG. 2, porosification system 200 can include illumination source 210, bath 220, and current source 230. In some aspects, a portion of a layer or substrate (e.g., in-plane or out-of-plane) can be exposed to an electrolyte current such that the portion is etched and a porous region remains. In some aspects, a porosity of the porous region can be controlled by adjusting electrolyte concentration, electrolyte current density, electrolyte current fluid velocity, porosification time, temperature, material doping, illumination power, and/or illumination wavelength. In some aspects, a thickness of the porous region can be controlled by adjusting a porosification (etching) time.

Illumination source 210 is configured to supplement EC etching of a layer or substrate (e.g., substrate 226) in bath 220 with PEC etching to form a porous region in the layer or substrate. PEC etching is dopant and bandgap selective and creates holes at the surface of the layer or substrate. Illumination source 210 can include a UV source (e.g., mercury lamp, arc lamp, etc.) and generate PEC illumination 212 over a portion or all of the layer or substrate. In some aspects, illumination source 210 can be a pulsed light source or include a mechanical modulator (e.g., chopper), an acousto-optical modulator (AOM), or an electro-optical modulator (EOM) to generate pulsed illumination having a particular frequency. In some aspects, illumination source 210 can have a power of about 1 mW to 10 W. In some aspects, illumination source 210 can include an optical filter to apply a particular wavelength(s) to the layer or substrate. In some aspects, illumination source 210 can be omitted for pure EC etching.

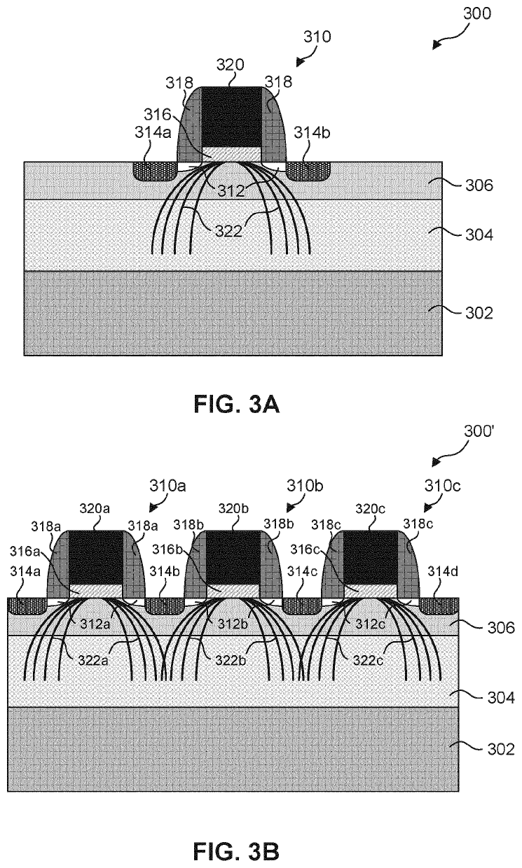

Bath 220 is configured to provide EC etching (e.g., chemical etch) of a layer or substrate (e.g., substrate 226) to form a porous region in the layer or substrate. Bath 220 can include electrolyte 222, electrode 224, and substrate 226 (e.g., substrate 302 shown in FIGS. 3A and 3B). In some aspects, electrolyte 222 can include any material (e.g., acid, alkali, oxidizer, salt, etc.) to facilitate EC etching of substrate 226. For example, electrolyte 222 can include hydrofluoric (HF) acid, buffered HF (5:2), hydrochloric (HCl) acid, hydrobromic (HBr) acid, sulfuric acid (H₂SO₄), nitric acid (HNO₃), oxalic acid (C₂H₂O₄), sodium hydroxide (NaOH), potassium hydroxide (KOH), hydrogen peroxide (H₂O₂), or any other suitable acid, alkali, salt, or oxidizer. Electrode 224 can include any suitable conductor (e.g., metal, copper (Cu), aluminum (Al), platinum (Pt), etc.). In some aspects, electrode 224 can include a doped semiconductor, for example, doped silicon (e.g., p-type). In some aspects, electrode 224 can include boron-doped diamond (BDD). For example, electrode 224 can include a silicon wafer coated with BDD. In some aspects, bath 220 can maintain a temperature of about 20° C. to about 60° C. In some aspects, substrate 226 can include substrate 302 or a portion (e.g., upper surface) of substrate 302 shown in FIGS. 3A and 3B. In some aspects, substrate 226 can be coupled to a holder such that one side of substrate 226 (e.g., frontside) is exposed to electrolyte 222 during EC etching while the opposite side of the substrate 226 (e.g., backside) is sealed and not exposed to electrolyte 222 during EC etching.

Current source 230 is configured to provide EC etching (e.g., current etch) of a layer or substrate (e.g., substrate 226) to form a porous region in the layer or substrate. Current source 230 can include cathode 232 and anode 234. When combined, current source 230 and bath 220 form an electrolyte current. In some aspects, as shown in FIG. 2, cathode 232 can be connected to electrode 224 and anode 234 can be connected to substrate 226 to complete the circuit. When current is applied, substrate 226 is etched (e.g., porosified), with or without illumination source 210, and electron flow is away from substrate 226 towards electrode 224. Electrons resonate at pore tips in substrate 226 and porosity extends through substrate 226. In some aspects, the electrolyte current density is about 1 mA/cm² to about 350 mA/cm². For example, the electrolyte current density can be about 10 mA/cm² to about 100 mA/cm². In some aspects, the lattice parameter of the starting material (e.g., substrate 226) remains relatively unchanged following the porosification process. In some aspects, a porosification rate in substrate 226 can be about 1 nm/min to about 25 μm/min. For example, the porosification rate can be about 0.1 μm/min to about 5 μm/min.

In some aspects, porosification system 200 can perform a porosification process (e.g., EC etch) on substrate 226 by exposing a portion of substrate 226 (e.g., frontside) to electrolyte 222 (e.g., buffered HF) and applying (passing) an electrolyzing current (e.g., in a range of 5 mA/cm² to 50 mA/cm²) through substrate 226 from cathode 232 and anode 234 for a specified time (e.g., for 10 seconds to 15 minutes). In some aspects, the porosification process can be carried out in a constant voltage mode (e.g., DC bias of about 5 V to about 20 V) and controlled by monitoring an etching current signal. In some aspects, the porosification process can be carried out in a constant current mode (e.g., DC current of about 5 A to about 20 A) and controlled by monitoring an etching current signal. In some aspects, the porosification process can include oxidation of substrate 226 by localized injection of holes upon application of a positive anodic bias (e.g., anode 234), and localized dissolution of such oxide layer in electrolyte 222 resulting in a porous layer (e.g., porous layer 304 shown in FIGS. 3A and 3B). In some aspects, the porosification process ends when the etching current signal drops to a base line level, indicating that all of the exposed portions of substrate 226 have been porosified and converted into a porous layer (e.g., porous layer 304 shown in FIGS. 3A and 3B).

In some aspects, substrate 226 can comprise any suitable substrate having a predetermined crystallographic orientation, including but not limited to silicon, germanium, and III-V semiconductors. In some aspects, substrate 226 can be doped prior to porosification to adjust a resistivity of substrate 226, for example, to a low-resistivity in a range of about 0.1 Ω·cm to 10 Ω·cm. In some aspects, electrolyte 222 can include a mixture of HF and deionized water, for example, having a ratio of (5:2) and surfactant (1 ml/l). In some aspects, electrolyte 222 can include a mixture of HF (e.g., 51%) and acetic acid (C₂H₄O₂) as a surfactant (e.g., 10 ml/l). In some aspects, electrolyte 222 can include a mixture of HF and an alcohol (e.g., ethanol), for example, having a ratio of (5:2).

In some aspects, porosification system 200 can form a porous layer (e.g., porous layer 304 shown in FIGS. 3A and 3B) that provides an epitaxy platform for subsequent regrowth of a defect-free, single crystal epilayer (e.g., epilayer 306 shown in FIGS. 3A and 3B). For example, porosification system 200 can form a porous layer (e.g., porous layer 304 shown in FIGS. 3A and 3B) with a low porosity (e.g., about 35%) such that the porous layer is relatively crystalline and long-range crystallinity of the porous layer is not significantly affected by the porosification process.

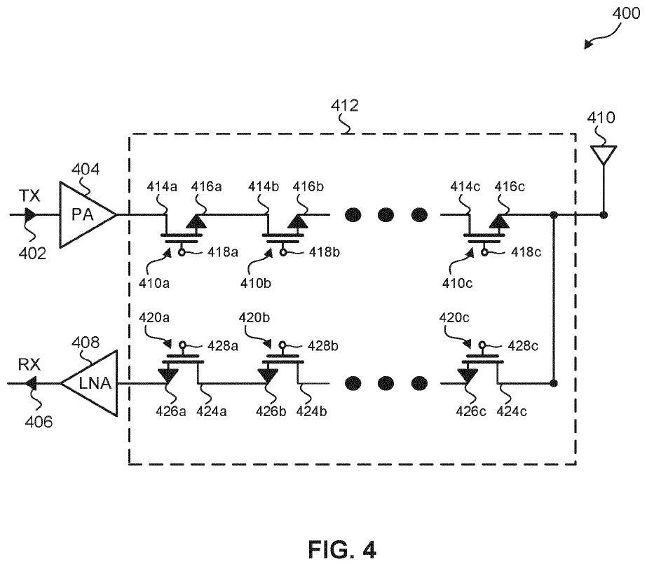

FIGS. 3A and 3B illustrate porous layered structures 300, 300′, according to exemplary aspects. Porous layered structures 300, 300′ can be configured to reduce signal leakage and suppress RF fringing fields (bleeding). In some aspects, porous layered structures 300, 300′ can be utilized in an RF device, for example, RF switch 412 shown in FIG. 4. Although porous layered structures 300, 300′ are shown in FIGS. 3A and 3B as stand-alone apparatuses and/or systems, aspects of this disclosure can be used with other apparatuses, systems, and/or methods.

As shown in FIG. 3A, porous layered structure 300 can include substrate 302 (e.g., silicon), porous layer 304 (e.g., porous silicon), epilayer 306 (e.g., single crystal silicon epilayer), and semiconductor device 310 (e.g., MOSFET) in epilayer 306. In some aspects, porous layered structure 300 with high-resistivity porous layer 304 (e.g., greater than about 5,000 Ω·cm) prevents RF field lines 322 from semiconductor device 310 from penetrating (bleeding) into substrate 302. In some aspects, porous layered structure 300 suppresses harmonic losses, reduces crosstalk, and reduces parasitic surface conduction effects.

In some aspects, substrate 302 can comprise any suitable substrate having a predetermined crystallographic orientation, including but not limited to silicon, germanium, and III-V semiconductors. In some aspects, substrate 302 can be doped prior to porosification to adjust a resistivity of substrate 302, for example, to a low-resistivity in a range of about 0.1 Ω·cm to 10 Ω·cm.

In some aspects, porous layer 304 can be a fully depleted porous layer (i.e., free of charge carriers). In some aspects, porous layer 304 can be a porous silicon layer. For example, porous layer 304 can be formed from a silicon substrate. In some aspects, porous layer 304 can have a resistivity greater than about 5,000 Ω·cm. In some aspects, porous layer 304 can have a thickness greater than about 10 microns. In some aspects, porous layer 304 can have a porosity of about 35% to 65%. In some aspects, pores in porous layer 304 can be mesoporous (e.g., 2 nm to 50 nm pore size).

In some aspects, epilayer 306 can be a defect-free, single crystal epilayer formed directly atop porous layer 304. In some aspects, epilayer 306 can comprise any suitable epilayer having a predetermined crystallographic orientation, including but not limited to silicon, germanium, and III-V semiconductors. In some aspects, epilayer 306 can have the same crystallographic orientation as substrate 302.

Semiconductor device 310 can include lightly doped regions 312, source/drain junctions 314a, 314b, gate oxide 316, spacers 318, and gate 320. Lightly doped regions 312 can be implanted with a dopant of a different type (e.g., n-type) than the corresponding epilayer 306 (e.g., p-type). Source/drain junctions 314a, 314b can be implanted with a dopant of the same type as adjacent lightly doped regions 312, but having a higher concentration than lightly doped regions 312. Gate oxide 316 can comprise an electrical insulator, for example, SiO₂. Spacers 318 can comprise an electrical insulator, for example, SiN. Gate 320 can comprise an electrical conductor, for example, polysilicon. In some aspects, semiconductor device 310 can be a transistor (e.g., MOSFET) in a CMOS device, for example, an RF switch (e.g., RF switch 412 shown in FIG. 4).

In some aspects the semiconductor device 310 can be formed directly in or on the porous layer 304 and the epilayer 306 be omitted. The semiconductor device 310 is therefore a passive device such as an inductor or filter.

The aspects of porous layered structure 300 shown in FIG. 3A, for example, and the aspects of porous layered structure 300′ shown in FIG. 3B may be similar. Similar reference numbers are used to indicate features of the aspects of porous layered structure 300 shown in FIG. 3A and the similar features of the aspects of porous layered structure 300′ shown in FIG. 3B.

As shown in FIG. 3B, porous layered structure 300′ can include a plurality of semiconductor devices 310a, 310b, 310c in epilayer 306. In some aspects, semiconductor devices 310a, 310b, 310c can be transistors, for example, MOSFETs. In some aspects, as shown in FIG. 3B, source/drain junction 314b can be shared by semiconductor devices 310a, 310b and source/drain junction 314c can be shared by semiconductor devices 310b, 310c. In some aspects, semiconductor devices 310a, 310b, 310c can be utilized in an RF device, for example, RF switch 412 shown in FIG. 4. For example, semiconductor devices 310a, 310b, 310c can generally correspond to transistors 410a, 410b, 410c (or transistors 420a, 420b, 420c) utilized in RF switch 412 shown in FIG. 4.

In some aspects the semiconductor devices 310a, 310b, 310c can be formed directly in or on the porous layer 304 and the epilayer 306 be omitted. The semiconductor devices 310a, 310b, 310c are therefore a passive device such as an inductor or filter.

FIG. 4 illustrates a circuit diagram of a portion of transceiver 400 with RF switch 412, according to an exemplary aspect. RF switch 412 can be configured to switch transceiver 400 between receive and transmit modes. In some aspects, transceiver 400 can be for a wireless communication device. Although transceiver 400 is shown in FIG. 4 as a stand-alone apparatus and/or system, aspects of this disclosure can be used with other apparatuses, systems, and/or methods.

As shown in FIG. 4, transceiver 400 can include transmit input (TX) 402, power amplifier (PA) 404, receive output (RX) 406, low-noise amplifier (LNA) 408, antenna 410, and RF switch 412. RF switch 412 is situated between PA 404 and antenna 410. PA 404 amplifies RF signals transmitted from transmit input 402. The output of PA 404 is coupled to one end of RF switch 412. Another end of RF switch 412 is coupled to antenna 410. Antenna 410 can transmit amplified RF signals. RF switch 412 is also situated between LNA 408 and antenna 410. Antenna 410 also receives RF signals. Antenna 410 is coupled to one end of RF switch 412. Another end of RF switch 412 is coupled to the input of LNA 408. LNA 408 amplifies RF signals received from RF switch 412. Receive output 406 receives amplified RF signals from LNA 408. In some aspects, RF switch 412 can employ stacked transistors.

RF switch 412 can include two stacks of transistors. The first stack includes transistors 410a, 410b, and 410c. Each transistor 410a, 410b, 410c has a corresponding drain 414a, 414b, 414c, source 416a, 416b, 416c, and gate 418a, 418b, 418c. The second stack includes transistors 420a, 420b, and 420c. Each transistor 420a, 420b, 420c has a corresponding drain 424a, 424b, 424c, source 426a, 426b, 426c, and gate 428a, 428b, 428c. When transistors 410a, 410b, and 410c are in OFF states, and transistors 420a, 420b, and 420c are in ON states, transceiver 400 is in receive mode. When transistors 410a, 410b, and 410c are in ON states, and transistors 420a, 420b, and 420c are in OFF states, transceiver 400 is in transmit mode. In some aspects, RF switch 412 can switch transceiver 400 between two transmit modes corresponding to different frequencies, or between two receive modes corresponding to different frequencies. In some aspects, RF switch 412 can be utilized in a semiconductor structure that reduces signal leakage.

### Exemplary System and Method for Controlling Porous Resistivity

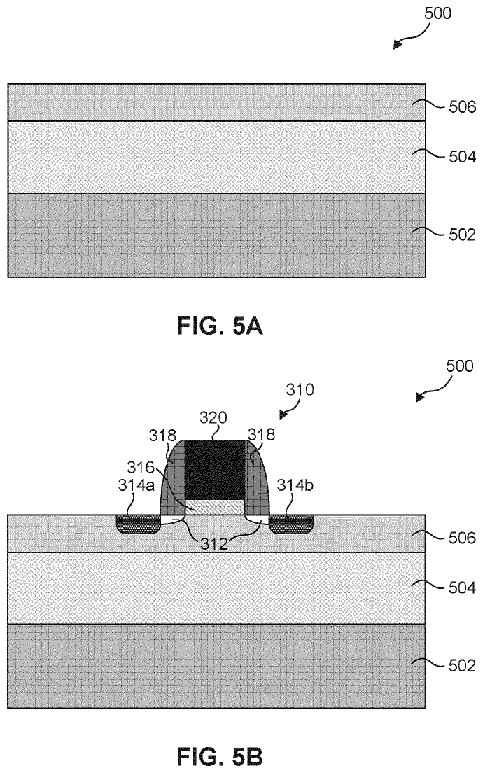

FIGS. 5A and 5B illustrate porous layered structure 500 according to exemplary aspects. The aspects of porous layered structure 500 shown in FIGS. 5A and 5B, for example, and the aspects of porous layered structure 300 shown in FIG. 3A may be similar. Similar reference numbers are used to indicate features of the aspects of porous layered structure 500 shown in FIGS. 5A and 5B and the similar features of the aspects of porous layered structure 300 shown in FIG. 3A. Porous layered structure 500 can be configured to reduce signal leakage and suppress RF fringing fields (bleeding). In some aspects, porous layered structure 500 can be utilized in an RF device, for example, RF switch 412 shown in FIG. 4. Although porous layered structure 500 is shown in FIGS. 5A and 5B as stand-alone apparatus and/or system, aspects of this disclosure can be used with other apparatuses, systems, and/or methods.

As shown in FIG. 5A, porous layered structure 500 can include substrate 502 (e.g., silicon), porous layer 504 (e.g., porous silicon), and optional epilayer 506 (e.g., single crystal silicon epilayer). Optionally, as shown in FIG. 5B, porous layered structure 500 can further include semiconductor device 310 (e.g., MOSFET) in epilayer 306. In some aspects, porous layered structure 500 with high-resistivity porous layer 504 prevents RF field lines 322 (as shown, for example, in FIG. 3A) from semiconductor device 310 from penetrating (bleeding) into substrate 502. In some aspects, porous layered structure 500 suppresses harmonic losses, reduces crosstalk, and reduces parasitic surface conduction effects. In some aspects, semiconductor device 310 (e.g. filter or inductor) is in porous layer 504 and epilayer 506 is omitted.

In some aspects, substrate 502 can comprise any suitable substrate having a predetermined crystallographic orientation, including but not limited to silicon, germanium, gallium nitride (GaN), and III-V semiconductors. In some aspects, substrate 502 can be doped prior to porosification to adjust a first resistivity 602 of substrate 502, for example, to a low-resistivity in a range of about 0.01 Ω·cm to 10 Ω·cm. As will be discussed in more detail below, varying the first resistivity 602 of substrate 502 may optimize and control a second resistivity 604 of the porous layer 504.

In some aspects, porous layer 504 can be a fully depleted porous layer (i.e., free of charge carriers). According the present disclosure, porous layer 504 is formed from substrate 502 by etching substrate 502 (e.g., EC etching). Porous layer 504 may have a second resistivity 604 that may be greater than the first resistivity 602 of substrate 502. The second resistivity 604 of porous layer 504 may be dependent on the first resistivity 602 of substrate 502 such that a correlation 610 may exist between the first resistivity 602 and the second resistivity 604. For example, a first resistivity 602 between about 0.01 Ω·cm and 10 Ω·cm of substrate 502 may yield a second resistivity 604 between 10 Ω·cm and 50,000 Ω·cm of porous layer 504. In some aspects, a first resistivity 602 of about 10 Ω·cm of substrate 502 may yield a second resistivity 604 greater than 50,000 Ω·cm of porous layer 504. For example, the second resistivity 604 can have a resistivity of about 50,000 Ω·cm to about 20 MΩ·cm.

In some aspects, epilayer 506 can be a defect-free, single crystal epilayer formed directly atop porous layer 504. In some aspects, epilayer 506 can comprise any suitable epilayer having a predetermined crystallographic orientation, including but not limited to silicon, germanium, gallium nitride (GaN), and III-V semiconductors. In some aspects, epilayer 506 can have the same crystallographic orientation as substrate 502.

As shown in FIG. 5B, porous layered structure 500 further includes semiconductor device 310. Semiconductor device 310 can include lightly doped regions 312, source/drain junctions 314a, 314b, gate oxide 316, spacers 318, and gate 320. Lightly doped regions 312 can be implanted with a dopant of a different type (e.g., n-type) than the corresponding epilayer 506 (e.g., p-type). Source/drain junctions 314a, 314b can be implanted with a dopant of the same type as adjacent lightly doped regions 312, but having a higher concentration than lightly doped regions 312. Gate oxide 316 can comprise an electrical insulator, for example, SiO₂. Spacers 318 can comprise an electrical insulator, for example, SiN. Gate 320 can comprise an electrical conductor, for example, polysilicon. In some aspects, semiconductor device 310 can be a transistor (e.g., MOSFET) in a CMOS device, for example, an RF switch (e.g., RF switch 412 shown in FIG. 4).

The second resistivity 604 of the porous layer 504 may be dependent on the first resistivity 602 of the substrate 502. As such, careful selection of the first resistivity 602 of the substrate 502 may control and optimize the second resistivity 604 of the porous layer 504. Advantageously such selection may ensure that the second resistivity 604 of the porous layer 504 may be high enough to yield better harmonic performance of the porous layered structure 500. For example, if a particular second resistivity 604 is desired in the porous layer 504, the substrate 502 and first resistivity 602 of the substrate 502 may be selected to achieve the desired second resistivity 604.

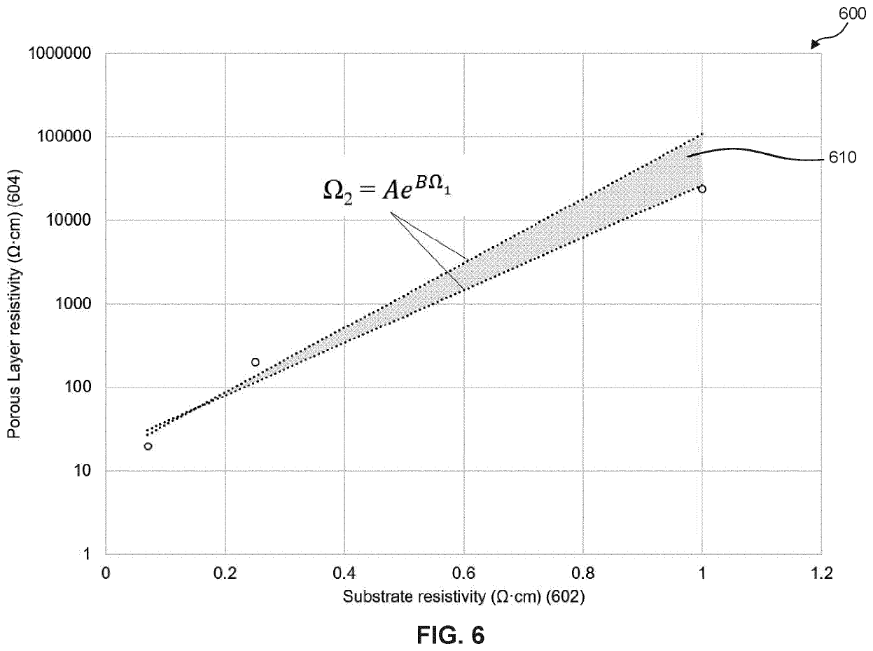

FIG. 6 illustrates a graph 600 (log-linear plot) showing a correlation 610 between the first resistivity (Ω₁) 602 of the substrate 502 and the second resistivity (Ω₂) 604 of the porous layer 504. As shown in FIG. 6, for example, as the first resistivity (Ω₁) 602 of the substrate 502 is increased, the second resistivity (Ω₂) 604 of the porous layer 504 increases exponentially. As such, the second resistivity (Ω₂) 604 of the porous layer 504 is dependent on the first resistivity (Ω₁) 602 of the substrate 502.

If it is desired to increase the second resistivity (Ω₂) 604 of the porous layer 504, a higher first resistivity (Ω₁) 602 of the substrate 502 may be selected to achieve the desired result. For example, if a porous layered structure 500 has a porous layer 504 with a second resistivity (Ω₂) 604 of about 20 Ω·cm that was manufactured using a substrate 502 with first resistivity (Ω₁) 602 of about 0.07 Ω·cm, the second resistivity (Ω₂) 604 may be increased in subsequent porous layered structures 500 by using a substrate 502 with first resistivity (Ω₁) 602 greater than 0.07 Ω·cm.

In some aspects, the second resistivity (Ω₂) 604 of the porous layer 504 is exponentially dependent on the first resistivity (Ω₁) 602 of the substrate 502. As shown in FIG. 6, for example, small incremental increases of the first resistivity (Ω₁) 602 of substrate 502 yield large increases in the second resistivity (Ω₂) 604 of porous layer 504. For example, a porous layered structure 500 that uses a substrate 502 with a first resistivity (Ω₁) 602 of about 0.25 Ω·cm may yield a porous layer 504 with a second resistivity (Ω₂) 604 of about 200 Ω·cm. Further, a porous layered structure 500 that uses a substrate 502 with a first resistivity (Ω₁) 602 of about 1 Ω·cm may yield a porous layer 504 with a second resistivity (Ω₂) 604 of greater than 24,000 Ω·cm. As such, an increase of first resistivity 602 of substrate 502 of about 0.75 Ω·cm may yield an increase of second resistivity 604 of porous layer 504 of 23,800 Ω·cm or greater.

In some aspects, the correlation 610 between the first resistivity (Ω₁) 602 of the substrate 502 and the second resistivity (Ω₂) 604 of the porous layer 504 can be quantified into an equation such that:

$${Ω}_{2} = A {e}^{B {Ω}_{1}}$$

where Ω₁ is the first resistivity (602), Ω₂ is the second resistivity (604), A is a first constant, and B is a second constant. In some aspects, A is a range between about 13 to 19.3, and B is a range between about 7 and 9.7. For example, where A is equal to 14 and B is equal to 8, for a substrate 502 having first resistivity (Ω₁) 602 of about 0.4 Ω·cm, the resultant porous layer 504 may have second resistivity (Ω₂) 604 of about 340 Ω·cm. However, if the first resistivity (Ω₁) 602 of substrate 502 is about 0.8 Ω·cm, the resultant porous layer 504 may have second resistivity (Ω₂) 604 of about 8,400 Ω·cm. Further, if the first resistivity (Ω₁) 602 of substrate 502 is about 1 Ω·cm, the resultant porous layer 504 may have second resistivity (Ω₂) 604 of about 41,700 Ω·cm. Multiple correlations 610 may be available by adjusting constants A and B in the equation above to give various values for second resistivity (Ω₂) 604 for different values of first resistivity (Ω₁) 602.

In some aspects, for example as shown in FIG. 6, for a selected first resistivity (Ω₁) 602 of the substrate 502, a range (shaded region shown in FIG. 6) of second resistivities (Ω₂) 604 of the porous layer 504 may be obtained according to the correlation 610 between the first resistivity (Ω₁) 602 and the second resistivity (Ω₂) 604. The correlation range 610 may be bound by the equation provided above and using minimum and maximum values for constants A and B such that:

$${A}_{min} {e}^{{B}_{min} {Ω}_{1}} < {Ω}_{2} < {A}_{max} {e}^{{B}_{max} {Ω}_{1}}$$

where Ω₁ is the first resistivity (602), Ω₂ is the second resistivity (604), Aₘᵢₙ is a first constant, Aₘₐₓ is a second constant, Bₘᵢₙ is a third constant, and Bₘₐₓ is a fourth constant. In some aspects, Aₘᵢₙ and Aₘₐₓ are a range between about 13 to 19.3, where Aₘᵢₙ<Aₘₐₓ, and Bₘᵢₙ and Bₘₐₓ are a range between about 7 and 9.7, where Bₘᵢₙ<Bₘₐₓ. For example, where Aₘᵢₙ is equal to 14, Aₘₐₓ is equal to 18, Bₘᵢₙ is equal to 7.5, and Bₘₐₓ is equal to 9, for a substrate 502 having first resistivity (Ω₁) 602 of about 0.5 Ω·cm, the resultant porous layer 504 may have second resistivity (Ω₂) 604 in the range of about 590 Ω·cm to about 1,620 Ω·cm. Multiple correlation ranges 610 may be available by adjusting constants Aₘᵢₙ, Aₘₐₓ, Bₘᵢₙ and Bₘₐₓ in the equation above to give various ranges for second resistivity (Ω₂) 604 for different values of first resistivity (Ω₁) 602.

In some aspects, the values of constants A and B may be dependent on the etching process used for the producing the porous layer 504. For example, A and B may be a first value based on an electrolyte current density. In another example, A and B may be a second value based on an electrolyte concentration (e.g., acid concentration) in the etching process. In some aspects, the values of constants A and B may be dependent upon the porosification conditions, for example, including but not limited to, electrolyte concentration, electrolyte current density, electrolyte current fluid velocity, anodization time, temperature, and/or material doping.

In some aspects, the first resistivity 602 may be between about 0.05 Ω·cm and about 0.10 Ω·cm, and the second resistivity 604 may be between about 15 Ω·cm and about 25 Ω·cm. In some aspects, the first resistivity 602 may be between about 0.20 Ω·cm and about 0.30 Ω·cm, and the second resistivity 604 may be between about 150 Ω·cm and about 250 Ω·cm. In some aspects, the first resistivity 602 may be between about 0.8 Ω·cm and about 1 Ω·cm, and the second resistivity 604 may be at least about 10,000 Ω·cm. In some aspects, the first resistivity 602 may be between about 1 Ω·cm and about 5 Ω·cm, and the second resistivity 604 may be at least about 24,000 Ω·cm. In some aspects, the first resistivity 602 may be greater than about 1 Ω·cm, and the second resistivity 604 may be greater than about 24,000 Ω·cm. In some aspects, the first resistivity 602 may be greater than about 1 Ω·cm, and the second resistivity 604 may be greater than about 1 MΩ·cm. In some aspects, the first resistivity 602 may be greater than about 5 Ω·cm, and the second resistivity 604 may be greater than about 20 MΩ·cm. In some aspects, the first resistivity 602 may be any value along the x-axis of the graph shown in FIG. 6, and the second resistivity 604 may be a corresponding value along the y-axis shown in FIG. 6.

### Exemplary Manufacturing Diagram

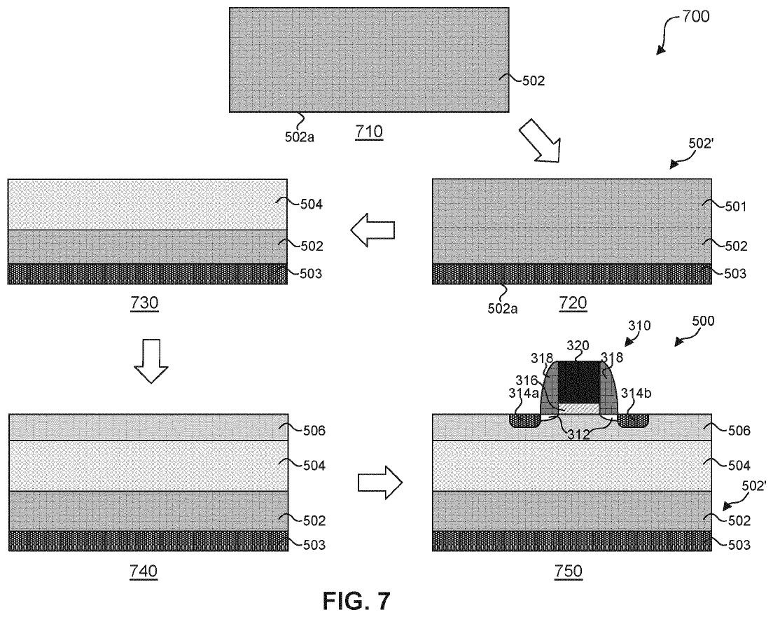

FIG. 7 illustrates an exemplary manufacturing diagram 700 for forming a porous layered structure 500 with a starting material layer substrate 502 and forming an epilayer 506, in accordance with some aspects of the present disclosure. Step 710 illustrates a substrate 502 with starting material having a first resistivity 602. The substrate includes a first surface 502a. Substrate 502 is selected as having a first resistivity 602 based on the desired second resistivity 604 of the porous layered structure 500. In some aspects, substrate 502 can be doped to reach a first resistivity 602 between about 0.01 Ω·cm and 10 Ω·cm. In some aspects, substrate 502 may have first resistivity 602 between about 0.05 Ω·cm and about 0.10 Ω·cm. In some aspects, substrate 502 may have first resistivity 602 between about 0.20 Ω·cm and about 0.30 Ω·cm. In some aspects, substrate 502 may have first resistivity 602 between about 0.8 Ω·cm and about 1 Ω·cm. In some aspects, substrate 502 may have first resistivity 602 between about 1 Ω·cm and about 5 Ω·cm.

Step 720 illustrates that the first surface 502a is treated for providing reliable electrical connection with an anode in an etching process. In some aspects, a portion 501 of substrate 502 may be exposed to an electrolyte current such that the portion 501 of the substrate 502 is etched to form the porous portion 504. The porosity of porous layer 504 may be configured by controlling the electrolyte concentration and/or applied current density

Step 730 illustrates the porous layered structure 500 after the etching process where the porous layer 504 has formed. Porous layer 504 may have a second resistivity 604 that is dependent on the first resistivity 602. In some aspects, porous layer 504 may have second resistivity 604 between about 10 Ω·cm and 50,000 Ω·cm. In some aspects, porous layer 504 may have second resistivity 604 between about 15 Ω·cm and about 25 Ω·cm. In some aspects, porous layer 504 may have second resistivity 604 between about 150 Ω·cm and about 250 Ω·cm. In some aspects, porous layer 504 may have second resistivity 604 of at least about 10,000 Ω·cm. In some aspects, porous layer 504 may have second resistivity 604 of at least about 24,000 Ω·cm. The porous layer 504 may be treated by post processing of the porous layer 504. The post processing can include drying the porous layer 504 and providing a sealing layer to prepare for application with additional layers or devices.

Step 740 illustrates an epilayer 506 epitaxially grown over the porous layer 504. The growth and/or deposition described herein may be performed using one or more of chemical vapor deposition (CVD), metalorganic chemical vapor deposition (MOCVD), organometallic vapor phase epitaxy (OMVPE), atomic layer deposition (ALD), molecular beam epitaxy (MBE), halide vapor phase epitaxy (HVPE), pulsed laser deposition (PLD), and/or physical vapor deposition (PVD). In some aspects, step 740 can be omitted from manufacturing diagram 700. In some aspects, step 740 can be omitted and porous layered structure 500 can include porous layer 504 on substrate 502 without epilayer 506, for example, as shown in step 730 of FIG. 7. In some aspects, porous layered structure 500 can include porous layer 504 on substrate 502 without epilayer 506 and porous layer 504 can include a semiconductor device or passive device in porous layer 504, for example, similar to semiconductor device 310 shown in step 750 of FIG. 7.

Step 750 illustrates a semiconductor 310 being coupled to the epilayer 506. Semiconductor device 310 can include lightly doped regions 312, source/drain junctions 314a, 314b, gate oxide 316, spacers 318, and gate 320.

It is to be understood that the phraseology or terminology herein is for the purpose of description and not of limitation, such that the terminology or phraseology of the present specification is to be interpreted by those skilled in relevant art(s) in light of the teachings herein.

The following examples are illustrative, but not limiting, of the aspects of this disclosure. Other suitable modifications and adaptations of the variety of conditions and parameters normally encountered in the field, and which would be apparent to those skilled in the relevant art(s), are within the spirit and scope of the disclosure.

While specific aspects have been described above, it will be appreciated that the aspects can be practiced otherwise than as described. The description is not intended to limit the scope of the claims.

The aspects have been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The foregoing description of the specific aspects will so fully reveal the general nature of the aspects that others can, by applying knowledge within the skill of the art, readily modify and/or adapt for various applications such specific aspects, without undue experimentation, without departing from the general concept of the aspects. Therefore, such adaptations and modifications are intended to be within the meaning and range of equivalents of the disclosed aspects, based on the teaching and guidance presented herein.

The breadth and scope of the aspects should not be limited by any of the above-described exemplary aspects, but should be defined only in accordance with the following claims and their equivalents.

1. A method for forming a layered structure, the method comprising:
forming a porous layer by electrochemical etching a portion of a substrate, the substrate having a first resistivity no greater than about 10 Ω·cm,
wherein the porous layer has a second resistivity greater than the first resistivity, and
wherein the second resistivity, Ω₂, is dependent upon the first resistivity, Ω₁, such that
Ω₂=Ae^{BΩ}^{₁}
wherein A is in a range between 13 and 19.3 and B is in a range between 7 and 9.7.

2. The method of claim 1, further comprising forming an epitaxial layer on the porous layer.

3. The method of claim 1, further comprising forming a device on the porous layer.

4. The method of claim 2, further comprising forming a device on the epitaxial layer.

5. A layered structure comprising:
a porous layer formed over a substrate, the substrate having a first resistivity no greater than about 10 Ω·cm and the porous layer having a second resistivity greater than the first resistivity,
wherein the second resistivity, Ω₂, is dependent upon the first resistivity, Ω₁, such that
Ω₂=Ae^{BΩ}^{₁}
wherein A is in a range between 13 and 19.3 and B is in a range between 7 and 9.7.

6. The layered structure of claim 5, wherein the first resistivity is between 0.01 Ω·cm and 10 Ω·cm, and the second resistivity is between 10 Ω·cm and 50,000 Ω·cm.

7. The layered structure of claim 5, wherein the first resistivity is between 0.8 Ω·cm and 1 Ω·cm, and the second resistivity is at least 10,000 Ω·cm.

8. The layered structure of claim 5, wherein the first resistivity is between 1 Ω·cm and 5 Ω·cm, and the second resistivity is at least 24,000 Ω·cm.

9. The layered structure of claim 5, wherein the second resistivity is at least 5,000 Ω·cm.

10. The layered structure of claim 5, wherein a ratio of the second resistivity to the first resistivity varies between 250 and 1,000.

11. The layered structure of claim 5, wherein a ratio of the second resistivity to the first resistivity is at least 10,000.

12. The layered structure of claim 5, further comprising an epitaxial layer formed on the porous layer.

13. The layered structure of claim 5, further comprising a device formed on the porous layer.

14. The layered structure of claim 12, further comprising a device formed on the epitaxial layer.
